(19) United States
(12) Patent Application Publication
(10) Pub. No.: US 2010/0194503 A1
(43) Pub. Date: Aug. 5, 2010

(54) Magnetic actuation mechanism

(75) Inventor: Marko Eromaki, Tampere (FI)

Correspondence Address: HARRINGTON & SMITH, 4 RESEARCH DRIVE, Suite 202, SHELTON, CT, 06484-6212, US

(73) Assignee: Nokia Corporation

(21) Appl. No.: 12/322,680

(22) Filed: Feb. 5, 2009

(51) Int. Cl. H01F 7/00; H05K 5/00

(52) U.S. Cl. 335/219; 361/679.01

(57) ABSTRACT

Disclosed herein is an apparatus. The apparatus includes a first movable member and a second movable member. The first movable member includes a magnet. The first movable member is configured to be connected to a first housing section of a portable electronic device. The second member includes a first end and a second end. The first movable member is between the first end and the second end. The second member is configured to be connected to a second housing section of the portable electronic device. The apparatus is configured to move the second housing section in a first direction in response to a first movement of the first movable member. The apparatus is configured to move the second housing section in a second different direction in response to a second movement of the first movable member.

### BACKGROUND

1. Field of the Invention

The invention relates to an electronic device and, more particularly, to a magnetic actuation mechanism for an electronic device.

2. Brief Description of Prior Developments

As electronic devices continue to become more sophisticated, these devices provide an increasing amount of functionality by including such applications as, for example, a mobile phone, digital camera, video camera, navigation system, gaming applications, and internet applications. Many of these devices include more than one configuration for utilization of these added functions. Slide phones are known in the art and have been widely used in different types of portable electronic devices to accommodate these configurations. Many of these conventional configurations comprise spring loaded, or spring-type, mechanisms configured for single-directional movement of a portion of a housing.

As consumers demand increased functionality from electronic devices, there is a need to provide improved devices having increased capabilities while maintaining robust and reliable product configurations.

### SUMMARY

In accordance with one aspect of the invention, an apparatus is disclosed. The apparatus includes a first movable member and a second movable member. The first movable member includes a magnet. The first movable member is configured to be connected to a first housing section of a portable electronic device. The second member includes a first end and a second end. The first movable member is between the first end and the second end. The second member is configured to be connected to a second housing section of the portable electronic device. The apparatus is configured to move the second housing section in a first direction in response to a first movement of the first movable member. The apparatus is configured to move the second housing section in a second different direction in response to a second movement of the first movable member.

In accordance with another aspect of the invention, an apparatus is disclosed. The apparatus includes a first housing section, a second housing section and a slide mechanism. The second housing section is movably connected to the first housing section. The slide mechanism is between the first housing section and the second housing section. The slide mechanism includes a rotatable member comprising a first magnet. The second housing section is configured to move in a first direction in response to a first rotation of the rotatable member.

In accordance with another aspect of the invention, an apparatus is disclosed. The apparatus includes a first housing section, a second housing section, and a slide mechanism. The second housing section is movably connected to the first housing section. The slide mechanism is between the first housing section and the second housing section. The slide mechanism comprises a first member and a second member. The first member includes a magnet. The slide mechanism is configured to drive the second housing section in a first direction in response to a magnetic attraction and/or a magnetic repulsion between a portion of the first member and a portion of the second member.

In accordance with another aspect of the invention, a method is disclosed. A first housing section is provided. A second housing section movably connected to the first housing section is provided. A slide mechanism between the first housing section and the second housing section is provided. The slide mechanism includes a first movable member having a magnet. The second housing section is configured to slide in a first direction in response to a first movement of the first movable member.

### BRIEF DESCRIPTION OF THE DRAWINGS

The foregoing aspects and other features of the invention are explained in the following description, taken in connection with the accompanying drawings, wherein:

FIG. 1 is a front view of an electronic device in a first (open) position incorporating features of the invention;

FIG. 2 is a front view of the electronic device shown in FIG. 1 in a second (closed) position;

FIG. 3 includes an enlarged exploded view and perspective view of a first member used in the electronic device shown in FIG. 1;

FIG. 4 is an enlarged a perspective view of a second member used in the electronic device shown in FIG. 1;

FIG. 5 is a front view of a slide mechanism used in the electronic device shown in FIG. 1;

FIG. 6 is a front view of the slide mechanism shown in FIG. 5 with a rotated first member;

FIG. 7 is a front view of the slide mechanism shown in FIG. 5 with the second member moved in a first direction;

FIG. 8 include front views of a magnet member and a magnet member with a surrounding yoke member used in the electronic device shown in FIG. 1;

FIG. 9 is a perspective view of an electronic device in accordance with another embodiment, in a first (open) position, incorporating features of the invention;

FIG. 10 is a perspective view of the electronic device shown in FIG. 9 in a second (closed) position;

FIG. 11 is another perspective view of the electronic device shown in FIG. 9 in a second (closed) position; and

FIG. 12 is a block diagram of an exemplary method of the electronic device shown in FIG. 1.

### DETAILED DESCRIPTION

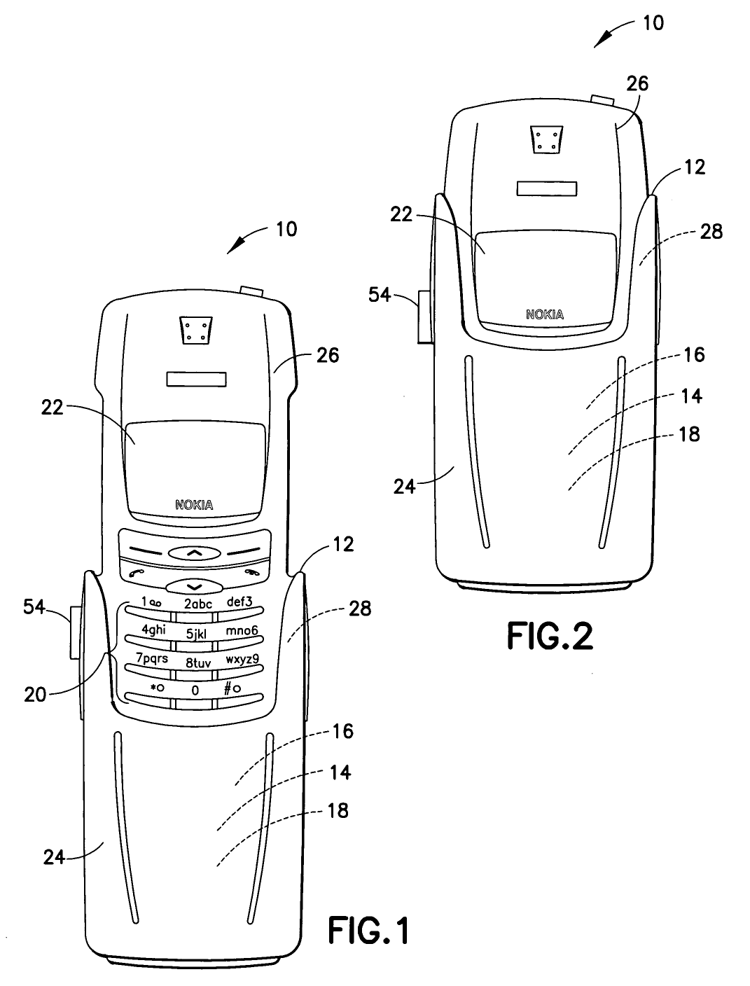

Referring to FIG. 1, there is shown a front view of an electronic device 10 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

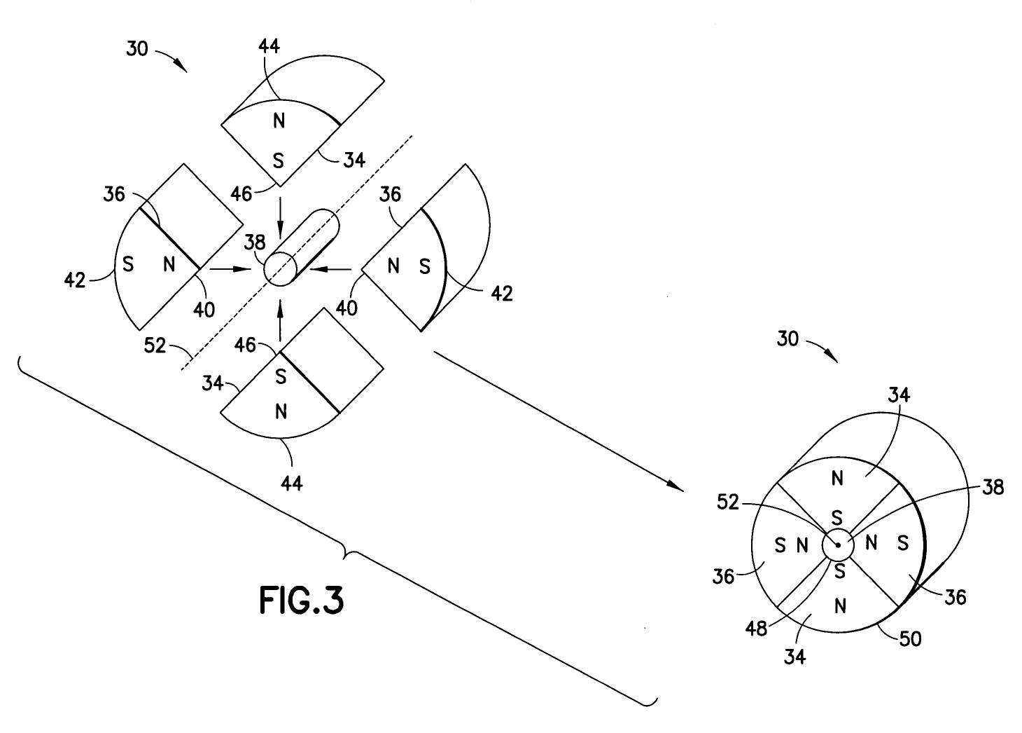

According to one example of the invention shown in FIGS. 1 and 2, the device 10 is a multi-function portable electronic device. However, in alternate embodiments, features of the various embodiments of the invention could be used in any suitable type of portable electronic device such as a mobile phone, a gaming device, a music player, a notebook computer, or a PDA, for example. In addition, as is known in the art, the device 10 can include multiple features or applications such as a camera, a music player, a game player, or an Internet browser, for example. The device 10 generally comprises a housing 12, a transceiver 14 connected to an antenna 16, electronic circuitry 18, such as a controller and a memory for example, within the housing 12, a user input region 20 and a display 22. The display 22 could also form a user input section, such as a touch screen. The housing 12 includes a first housing section 24 and a second housing section 26. According to various exemplary embodiments of the invention, the display 22 and the user input region 20 are provided on the second housing section 24. However, any suitable configuration may be provided. Additionally, it should be noted that in alternate embodiments, the device 10 can have any suitable type of features as known in the art.

The first housing section 24 and the second housing section 26 are movably connected to each other. In particular, the first housing section 24 and the second housing section 26 are slidably connected to each other wherein the second housing section 26 may be configured to slide between a first position (or open position) as shown in FIG. 1, and a second position (or closed position) as shown in FIG. 2. However, it should be noted that in alternate embodiments, any movable housing section configuration allowing for relative movement or sliding between the first housing section and the second housing section may be provided. For example, according to one embodiment, the first housing section may be configured to slide between a first position (or open position) and a second position (or closed position) relative to the second housing section. According to various exemplary embodiments of the invention, the first housing section may comprise relatively high side walls wherein only a small portion (including the display, for example) of the second housing section (or inner block) remains visible when in the closed position. However, this is not required and any suitable configuration may be provided.

The electronic device further comprises a slide mechanism 28 between the first housing section 24 and the second housing section 26. According to various exemplary embodiments of the invention, members comprising magnets (or magnetic members) may be provided to drive the sliding mechanism 28. The slide mechanism 28 may utilize magnetic attraction and/or repulsion (which may be used simultaneously) of the magnetic members to provide the driving force. The driving force may, for example, drive the sliding mechanism 28 (to move) between the open position and the closed position (of the housing sections relative to one another).

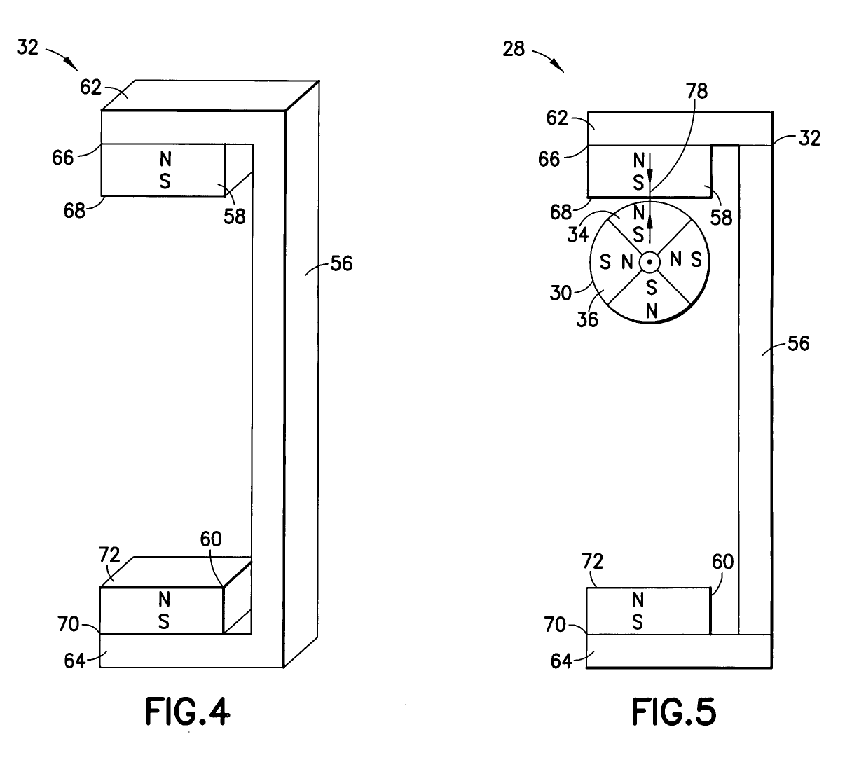

Referring now also to FIGS. 3 and 4, the slide mechanism 28 comprises a first member 30 and a second member 32. The first member 30 may be connected to the first housing section 24. The second member 32 may be connected to the second housing section 26. The first and second members 30, 32 may be connected to the first and second housing sections 24, 26 in any suitable fashion which allows for a slidable connection between the first housing section 24 and the second housing section 26. It should be noted that alternate embodiments may provide for the slide mechanism 28 to be disposed within the housing 12 in any suitable fashion, for example, the first member may be connected to the second housing section and the second member may be connected to the first housing section. However, any suitable member and housing section configuration may be provided. Additionally, any suitable number of members, housing sections, and/or slide mechanisms may be provided.

The first member 30 may be a movable member comprising a plurality of magnets. In the embodiment shown in FIGS. 3 and 5-7, the first member 30 may comprise four magnets 34, 36 arranged about a pivot axle 38. The magnets 34, 36 may comprise a general pie (or wedge) shape and may be adjacent each other as shown in the figures such that the magnets 34, 36 form a rotating magnetic cylinder. However, the wedge shape is not required and any suitable shape (or number of magnets) may be provided. Additionally, although the figures show the first member 30 as having a cylindrical shape, any suitable shape may be provided.

The magnets 34, 36 may be permanent magnets. However, any other suitable type (or combination) of magnets, such as electromagnets for example, may be provided.

Each of the magnets 36 comprises a north (N) pole at a narrow end 40 of the wedge shape and a south (S) pole at a wide end 42 of the wedge shape. The magnets 34 each comprise a north (N) pole at a wide end 44 of the wedge shape and a south (S) pole at a narrow end 46 of the wedge shape. With the narrow ends 40, 46 and the wide ends 42, 44 adjacent each other, the magnets 34, 36 form a cylindrical member wherein the narrow ends 40, 46 form an inside (or inner) diameter 48 and the wide ends 42, 44 form an outside (or outer) diameter 50.

The magnets 34, 36 may be attached to the pivot axle 38 by any suitable fastening means (or connection type), such as by gluing for example. The magnets 34, 36 may be arranged such that their respective polarities (N, S) are inversely oriented with respect to each other. For example, the magnets 36 may have their north (N) poles proximate the inner diameter 48 (around the pivot axle 38), and the magnets 34 may have their north (N) poles proximate the outer diameter 50 (opposite ends from the pivot axle 38). However, any suitable magnet pole orientation may be provided.

The pivot axle 38 may be movably connected to the first housing section 24 to form a pivot axis 52 for the rotatable cylindrical member 30. The pivot axle 38 may be movably connected, or mounted, to the first housing section 24 in any suitable fashion. For example, the pivot axle 38 may be connected to the first housing section 24 by a fastener configuration, or a fastener and bearing configuration, or a fastener and washer configuration. However, any suitable type connection allowing for the pivot axle to rotate or pivot may be provided. The movable connection between the pivot axle 38 and the first housing section 24 provides for rotation or pivoting of the magnetic cylinder 30 as the magnets 34, 36 move/rotate together (in unison), thus allowing for the magnets 34, 36 and axle 38 to form a cylindrical actuator switch.

Additionally, the pivot axle 38 (along with the magnets 34, 36) is configured to move, by pivoting or rotating for example, in response to a movement of a button (or lever) 54 on the housing (see FIGS. 1 and 2). The button 54 may be connected to the pivot axle 38 of the rotating member 30 to transfer movement by any suitable means, such as, a direct connection, a gear system, a pulley system, and/or a lever system, for example. However, any configuration allowing for the transfer of movement between the button (or lever) 54 and the rotating member 30 may be provided.

The second member 32 may comprise a slider bar 56, a first slider bar magnet 58, and a second slider bar magnet 60. The slider bar 56 may comprise a general “U” shape having a first end 62 and a second end 64. However, any suitable shape may be provided. The first slider bar magnet 58 may be provided at the first end 62. The second slider bar 60 magnet may be provided at the second end 64. The ends 62, 64 of the slider bar 56 may extend such that the rotating member 24 is between the ends 62, 64 wherein the first slider bar magnet 58 is opposite one of the magnets 34, 36 of the rotating member 30 and wherein the second slider bar magnet 60 is opposite another one of the magnets 34, 36 of the rotating member 30.

The magnets 58, 60 may be attached to the ends 62, 64 of the slider bar 56 by any suitable means, such as by gluing or mechanical fastening for example. However, any suitable fastening configuration (or connection type) may be provided. The first slider bar magnet 58 may be arranged such that an attached end 66 of the slider bar magnet 58 comprises a north (N) pole of the magnet and a free end 68 of the of the slider bar magnet comprises a south (S) pole of the magnet. The second slider bar magnet 60 may be arranged such that an attached end 70 of the slider bar magnet comprises a south (S) pole of the magnet and a free end 72 of the of the slider bar magnet comprises a north (N) pole of the magnet. However, any suitable magnet pole orientation may be provided. Additionally, it should be noted that although the figures illustrate the magnets as having a general rectangular volume shape, any suitable shape may be provided.

According to various exemplary embodiments of the invention, the second member (or U-shaped slider bar member) 32 may be connected to the second housing section 26 by any suitable fastening means. However, alternate embodiments may provide for the slider bar to be integral with the second housing section wherein the shape of the U-bar can be integrated to the moving elements on a mobile device leaving only the magnets as additional parts.

The magnets 58, 60 may be permanent magnets. However, any other suitable type (or combination) of magnets, such as electromagnets for example, may be provided.

Referring now also to FIGS. 5-7, the slide mechanism 28 may be setup so that the rotating magnetic cylinder 30 may be pivoted (see arrow 74), to allow for rotation (as the rotating magnetic cylinder is movably connected to the first housing section 24) and the U-bar member 32 is allowed to slide up and down (see arrow 76), thus moving the second housing section 26 between the open and closed positions. In the initial state, one of the north poles on the cylindrical magnet 34 is attracting the south pole of the upper magnet 58 on the U-bar member 32 (see FIG. 5). Magnetic force (see force arrows 78) creates a suitable hold power to keep (or lock) the slide mechanism system 28 in a static state.

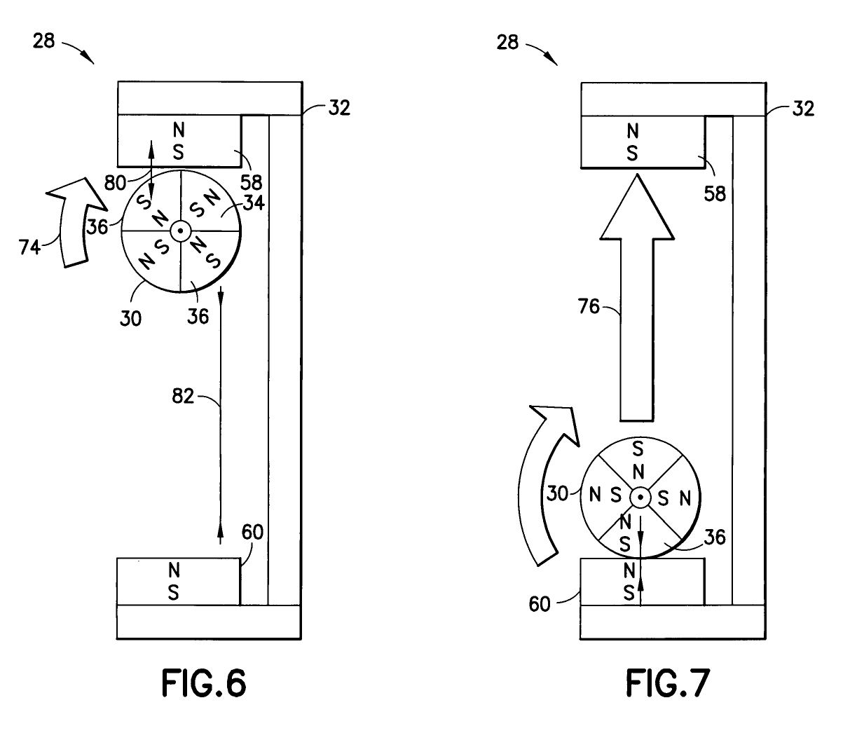

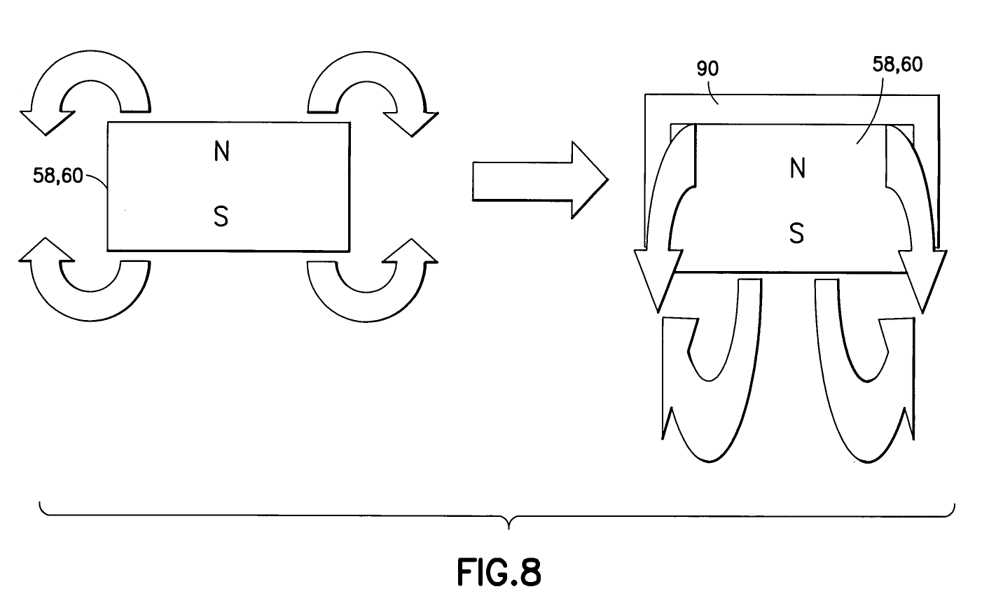

When the cylindrical magnet 30 is slightly rotated clockwise (for example, when a user moves the button 54), one of the south poles of the magnet 36 is turning against the south pole of the upper U-bar magnet 58 (see FIG. 6), and the magnet 36 and the magnet 58 start to repel each other (see force arrows 80). At the same time, one of the south poles of the opposite magnet 36 is turning against the lower U-bar magnet 60 causing attraction to the north pole (see force arrows 82). This provides sufficient forces to move the second housing section 26 (comprising the display 22, user input region 20, and/or an associated FPC connection, for example). After the cylindrical magnet 30 is rotated a full ninety degrees, rapid sliding movement occurs when the upper repelling magnet pair 36, 38 “kicks” the system into movement upwards (and which the lower attracting magnet pair 36, 60 will enhance), in the direction 76, and the slide bar member 32 will finally stop after the magnets 36, 60 stick to each other (see FIG. 7). The resulted static state is maintained with the magnetic holding power between magnets 36, 60. Movement to the opposite direction (opposite of direction 76) occurs by rotating the cylindrical magnet 90 degrees in counter-clockwise direction (for example, when the user moves the button 54 again). The polarity of the “input” magnet 30 may be reversed by rotating it ninety degrees in order to reverse the open/closed state of the slide mechanism 28. This allows for the device 10 to be both opened and closed by a small rotation of the input magnet 30.

By providing attraction and repulsion forces between the magnets, relatively long (stroke) movements and relatively high masses (such as about 25 grams, for example) can be moved.

According to another embodiment of the invention, a yoke part 90 may be provided around the magnets 58, 60. The yoke part 90 may have a general “U” shape (or cup shape) and may be fabricated from a sheet metal material, such as ferrite (iron) for example. However, any suitable material may be provided. The yoke part 90 may be provided to control and limit the direction of the magnetic field generated by the magnets 58, 60. The yoke part 90 may also increase the magnetic field performance (or strength) and increase the thrust of the slide mechanism. The yoke part 90 may also provide for the magnetic field effect to be minimized from affecting the electronic circuitry or components of the device, such as RF elements, for example.

The yoke part 90 may be attached to the second member 32 between the magnets 58, 60 and the slider bar 56 by any suitable fastening means. It should be noted that in alternate embodiments, the yoke part 90 may be integral with the slider bar. However, any suitable configuration may be provided. In addition, the yoke part allows the slide mechanism to be configured and operate in a similar fashion as described above.

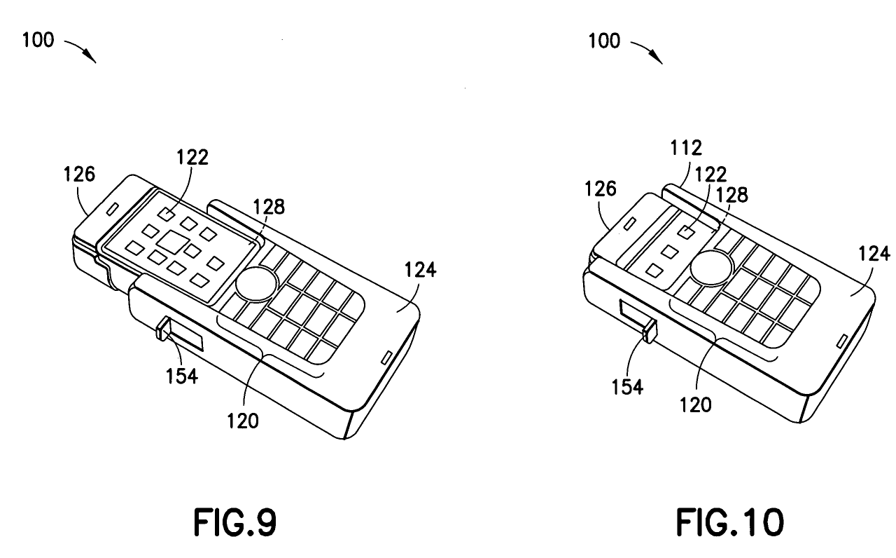

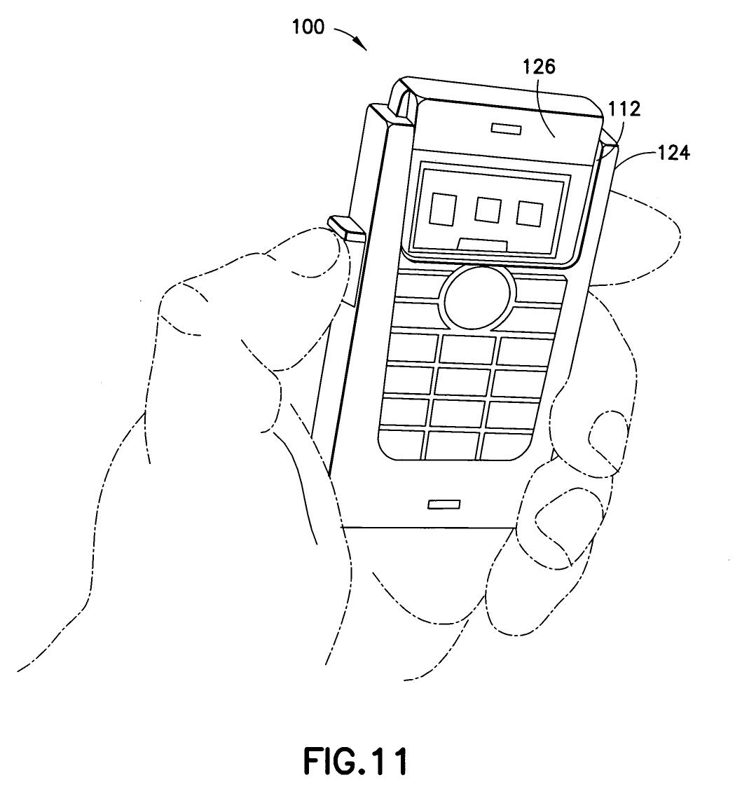

According to another embodiment of the invention, a device 100 may be provided as shown in FIGS. 9-11. The device 100 is similar to the device 10 and is configured, in a similar fashion as described above, to slide housing sections relative to each other between open (see FIG. 9) and closed (see FIGS. 10 and 11) positions when a user moves a button or lever 154 of the device 100.

The device 100 comprises a housing 112 having a first housing section 124 and a second housing section 126 with a slide mechanism 128 connected therebetween. However, the device 100 provides for viewing the entire display 122 when the device 100 is in the open position, and for viewing a portion of the display 122 when the device is in the closed position. Additionally, the device 100 provides the user input region 120 on the first housing section 124 instead of the second housing section. This provides for the user input region 120 to be accessible in either the open or closed positions. It should be understood that in alternate embodiments any suitable device housing, display and/or user input region configuration maybe provided.

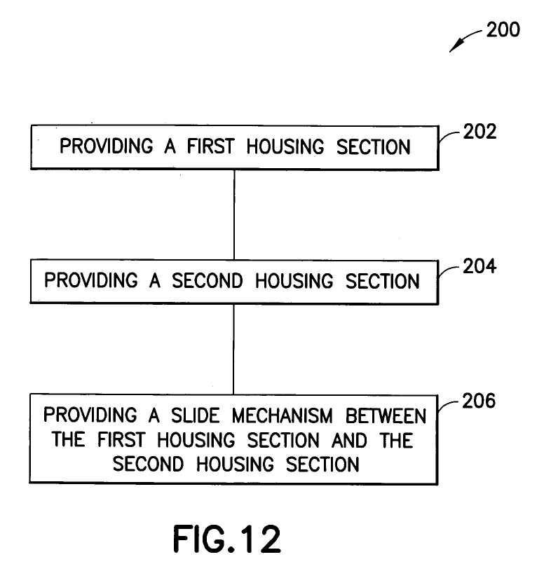

FIG. 12 illustrates a method 200. The method 200 includes the following steps. Providing a first housing section (step 202). Providing a second housing section movably connected to the first housing section (step 204). Providing a slide mechanism between the first housing section and the second housing section (step 206). The slide mechanism comprises a first movable member comprising a magnet. The second housing section is configured to slide in a first direction in response to a first movement of the first movable member. It should be noted that any of the above steps may be performed alone or in combination with one or more of the steps.

Technical effects of any one or more of the exemplary embodiments provide a dual-movement magnetic actuation mechanism 28, 128 enabling easier mobile electronic device usage when compared to conventional configurations (such as single-directional spring loaded “pop-up” mechanisms, snap-action-spring type mechanisms, or frictional slider solutions, for example). Many of the conventional devices have a buckling point for the spring that pushes the slider to the end position after certain point of travel. Typically the travel (or initiated movement by the user) needed for the conventional mechanisms to work is about fifty percent of the stroke. Some examples of the invention provide a slider mechanism wherein the movement of the user operable slider button is about twenty percent of the total stroke. In addition, various exemplary embodiments of the invention allow for full two-directional movement while maintaining a robust, non-power consuming, and inexpensive configuration.

According to one example of the invention, an apparatus is disclosed. The apparatus includes a first movable member and a second movable member. The first movable member includes a magnet. The first movable member is configured to be connected to a first housing section of a portable electronic device. The second member includes a first end and a second end. The first movable member is between the first end and the second end. The second member is configured to be connected to a second housing section of the portable electronic device. The apparatus is configured to move the second housing section in a first direction in response to a first movement of the first movable member. The apparatus is configured to move the second housing section in a second different direction in response to a second movement of the first movable member.

According to another example of the invention, an apparatus is disclosed. The apparatus includes a first housing section, a second housing section and a slide mechanism. The second housing section is movably connected to the first housing section. The slide mechanism is between the first housing section and the second housing section. The slide mechanism includes a rotatable member comprising a first magnet. The second housing section is configured to move in a first direction in response to a first rotation of the rotatable member.

According to another example of the invention, an apparatus is disclosed. The apparatus includes a first housing section, a second housing section, and a slide mechanism. The second housing section is movably connected to the first housing section. The slide mechanism is between the first housing section and the second housing section. The slide mechanism comprises a first member and a second member. The first member includes a magnet. The slide mechanism is configured to drive the second housing section in a first direction in response to a magnetic attraction and/or a magnetic repulsion between a portion of the first member and a portion of the second member.

Technical effects of any one or more of the exemplary embodiments provide a magnetically operated, semi-automatic sliding mechanism 28, 128 for a portable electronic device. Some conventional configurations have used magnets to bias a slide portion to its open or closed position. However, examples of the invention provide an improved configuration which also uses magnetic attraction and/or repulsion to drive the housing sections from open to closed (or vice versa) positions for the entire length of travel.

Additional technical effects of any one or more of the exemplary embodiments provide a slider mechanism which enables long two-directional movement for the slider block (or second housing section) with a shorter stroke from an actuator button. Many conventional configurations provide a separate spring loaded, single movement, slider element with rails. These conventional configurations generally only enhance the initiated manual movement by the user. Instead, various examples of the invention provide a dual direction automated sliding system wherein with touch of a button, the inner block (or second housing section) is configured to “pop-out”, and slide back in when the button is pressed a second time.

Additionally, various examples of the invention may provide for the use of magnets to drive the slide mechanism which allows for a short length of human input required to generate a large output travel. The input magnet (or rotating magnetic member) can be rotated by using a small movement of the user's thumb/finger on the actuator button/lever of the device (this changes the mutual position of the magnets to provide for attracting and repelling forces to be generated between the magnets), as opposed to the large movement required to open or close a conventional slide. Additionally, various embodiments of the invention contain no springs, and therefore may not be subject to spring fatigue reliability problems.

Further technical effects of any one or more of the exemplary embodiments provide significant improvements over conventional configurations (such as NOKIA® Model Nos. N80, 6270, 6280, 6500, 8110, 8800, and 8910, for example) by enabling single hand or single finger operation for mobile devices with sliding elements. Additionally, as no springs or electrical motors are required, there are no wearing parts on the actuation mechanism and electricity is not needed (which conserves battery power, for example). Further, some examples of the invention enables “ease-of-use” for slider phone constructions where one section of the housing may be hidden inside the other section of the housing and only a portion of it may be visible, such as part of display, for example. Yet further, some examples of the invention provide high hold forces which may lock the sliding parts (or housing sections) at end positions. Further, various embodiments of the invention allow for manual opening and closing of the housing sections without damage occurring to the actuation mechanism. Yet further, various embodiments of the invention provide a robust and substantially inexpensive configuration for two directional movement slide devices.

It should be understood that components of the invention can be operationally coupled or connected and that any number or combination of intervening elements can exist (including no intervening elements). The connections can be direct or indirect and additionally there can merely be a functional relationship between components.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

1. An apparatus comprising:
a first movable member comprising a magnet, wherein the first movable member is configured to be connected to a first housing section of a portable electronic device; and
a second member comprising a first end and a second end, wherein the first movable member is between the first end and the second end, wherein the second member is configured to be connected to a second housing section of the portable electronic device, wherein the apparatus is configured to move the second housing section in a first direction in response to a first movement of the first movable member, and wherein the apparatus is configured to move the second housing section in a second different direction in response to a second movement of the first movable member.

2. An apparatus as in claim 1 wherein the apparatus is configured to hold the second housing section in a first position and a second position.

3. An apparatus as in claim 1 wherein the second member is a bar member comprising a general “U” shape.

4. An apparatus as in claim 1 wherein the second member comprises at least one magnet opposite the first movable member.

5. An apparatus as in claim 1 wherein the apparatus is configured to drive the second housing section in the first and the second directions in response to a magnetic attraction and/or a magnetic repulsion between a portion of the first movable member and a portion of the second member.

6. A device comprising:
a first housing section;
a second housing section movably connected to the first housing section; and
an apparatus as in claim 1 between the first housing section and the second housing section.

7. An apparatus comprising:
a first housing section;
a second housing section movably connected to the first housing section; and
a slide mechanism between the first housing section and the second housing section, wherein the slide mechanism comprises a rotatable member comprising a first magnet, and wherein the second housing section is configured to move in a first direction in response to a first rotation of the rotatable member.

8. An apparatus as in claim 7 wherein the second housing section is configured to move in a second different direction in response to a second rotation of the rotatable member.

9. An apparatus as in claim 7 wherein the rotatable member further comprises a second magnet.

10. An apparatus as in claim 9 wherein the first magnet and the second magnet are adjacent each other and arranged about a pivot axle.

11. An apparatus as in claim 9 wherein the first magnet and the second magnet are mounted for movement in unison about a pivot axis.

12. An apparatus comprising:
a first housing section;
a second housing section movably connected to the first housing section; and
a slide mechanism between the first housing section and the second housing section, wherein the slide mechanism comprises a first member and a second member, wherein the first member comprises a magnet, and wherein the slide mechanism is configured to drive the second housing section in a first direction in response to a magnetic attraction and/or a magnetic repulsion between a portion of the first member and a portion of the second member.

13. An apparatus as in claim 12 wherein the slide mechanism is configured to drive the second housing section in a second direction in response to another magnetic attraction and/or another magnetic repulsion between another portion of the first member and another portion of the second member.

14. An apparatus as in claim 12 wherein the second member comprises a magnet, and wherein the slide mechanism is configured to drive the second housing section in the first direction in response to a magnetic attraction and/or a magnetic repulsion between the magnet of the first member and the magnet of the second member.

15. An apparatus as in claim 12 wherein the first member is between opposite ends of the second member, and wherein the first member is rotatable about a pivot axis.

16. An apparatus as in claim 12 wherein the second member is a bar member comprising a general “U” shape.

17. A method comprising:
providing a first housing section;
providing a second housing section movably connected to the first housing section; and
providing a slide mechanism between the first housing section and the second housing section, wherein the slide mechanism comprises a first movable member comprising a magnet, and wherein the second housing section is configured to slide in a first direction in response to a first movement of the first movable member.

18. A method as in claim 17 wherein the providing of the slide mechanism further comprises providing the slide mechanism comprising the first movable member, wherein the first movable member is rotatable.

19. A method as in claim 17 wherein the providing of the slide mechanism further comprises providing the slide mechanism comprising a second member, wherein the first movable member is between ends of the second member.

20. A method as in claim 19 wherein the providing of the slide mechanism further comprises providing the slide mechanism comprising the second member, wherein the second member comprises at least one magnet opposite the first movable member.
